(19) United States
(12) Patent Application Publication
(10) Pub. No.: US 2025/0257081 A1
(43) Pub. Date: Aug. 14, 2025

(54) HIGH PURITY TIN COMPOUNDS CONTAINING FLUOROALKOXY SUBSTITUENT AND METHODS FOR PREPARATION THEREOF

(71) Applicants: Gelest, Inc., Morrisville, PA (US); Mitsubishi Chemical Corporation, Tokyo (JP)

(72) Inventors: Li YANG, Belle Mead, NJ (US); Yuta HIOKI, Tokyo (JP); Christopher Michael CAROFF, Yardley, PA (US)

(21) Appl. No.: 19/045,914

(22) Filed: Feb. 5, 2025

Related U.S. Application Data
(60) Provisional application No. 63/551,655, filed on Feb. 9, 2024.

(51) Int. Cl. C07F 7/22

(52) U.S. Cl. CPC C07F 7/2224; C07F 7/2284

(57) ABSTRACT

Monoorgano tin trialkoxide compounds having chemical formula R′SnX₃ and containing less than about 5 mol % R′₂SnX₂ are described. R′ is an optionally substituted organic substituent having about 1 to about 20 carbon atoms and each X is independently OR_{f}, wherein R_{f} is a fluorinated organic substituent having about 1 to about 20 carbon atoms. Methods for synthesizing and purifying these compounds are also provided. The monoorgano tin compounds may be used for the formation of high-resolution EUV lithography patterning precursors and are attractive due to their high purity and minimal concentration of diorgano tin impurities.

### CROSS-REFERENCE TO RELATED APPLICATION

This application claims priority to U.S. provisional patent application No. 63/551,655, filed Feb. 9, 2024, the disclosure of which is herein incorporated by reference in its entirety.

### BACKGROUND OF THE INVENTION

As semiconductor fabrication continues to advance, feature sizes continue to shrink, driving the need for new processing methods. Certain organotin compounds have been shown to be useful in the deposition of tin oxide hydroxide coatings in applications such as extreme ultraviolet (EUV) lithography techniques. For example, tin compounds containing alkoxy substituents provide radiation sensitive Sn—C bonds that can be used to pattern structures lithographically.

Materials used in microelectronic fabrication are required to be extremely pure with tight limits placed on organic contamination (e.g., reaction by-products), metallic contamination, and particulate contamination. Purity requirements are stringent in general, and particularly for lithography applications because the chemical is in contact with the semiconductor substrates and the organometallic impurities in compounds such as diisopropylbis(dimethylamino)tin, (iPr)₂Sn(NMe₂)₂, can affect the properties of the resultant film. Exact targets for purities are determined by a variety of factors, including performance metrics, but typical minimum purity targets are 3N+. Residual metals present in the chemicals can be deposited onto the semiconductor substrate and degrade the electrical performance of the device being fabricated. Typical specifications for metals are less than 10 ppb for individual metals and total metal not to exceed ˜100 ppb.

The processing and performance of semiconductor materials may also be sensitive to dialkyl tin contaminants. Dialkyl tin impurities such as R₂Sn(NMe₂)₂, where R is an alkyl group, are the source of off-gassing after vapor phase deposition or spin-on coating processes due to the oxostannate cluster films being less dense when the film contains dialkyl groups. To produce microelectronic products using EUV lithography, proper control of dialkyl tin contaminants is required. The high purity required from the mono-alkyl tin precursor manufacturing process becomes a challenge. In general, the syntheses of monoalkyl tin triamides have previously employed lithium dimethylamide reagents reacted with alkyl tin trichloride, or followed by a lithium/Grignard reagent (alkylating agent) to convert the tin tetraamides to the desired triamides.

However, similar synthetic methods are not applicable for the synthesis of tin compounds containing unstable functional groups such as unsaturated functional groups (including, for example, vinyl, allyl, alkenyl, alkynyl, phenyl, and benzyl), heteroatom-containing functional groups (such as those containing oxygen, nitrogen, and/or sulfur, including, for example, ether, (alkyl)amino, and (alkyl)thiol groups). Rather, the lithium dimethyl amide strong base will react not only with the tin-chlorine bond, but also with the double or triple bond on the organic substituent. Further, primary and secondary monoorgano tin compounds cannot be synthesized from an alkylating agent and a tetraamide even when using the correct stoichiometry: a primary alkylating agent will convert a tin tetraamide to a trialkyltin amide and unreacted tetraamide, and a secondary alkylating agent will convert a tin tetraamide to polyalkyl tin compounds. An alternative approach is required to synthesize high purity tin compounds containing unsaturated substituents and dimethylamide ligands.

Further, monoalkenyl tin trialkoxides cannot be prepared via the reaction of the corresponding tin triamide with an alcohol, and reaction of an organotin trichloride with dialkylamine followed by reaction with alcohol leads to a mixture of products.

Graf (“Tin, Tin Alloys, and Tin Compounds,” Ullmann's Encyclopedia of Industrial Chemistry; Weinheim: Wiley-VCH (2005)) reports the preparation of monoorgano tin trichlorides containing vinyl or allyl substituents without a catalyst or heat using Kocheshkov comproportionation; the electron donating group enables the comproportionation. As a result, the unsaturated/electron donating group from both the alkenyl or alkoxy group may promote the Kocheshkov-like comproportionation during the reaction especially when preparing mono-vinyl or mono-allyl tin trialkoxy compounds according to scheme (I), shown below, and the disproportion during purification scheme (II), resulting in a mixture of products.

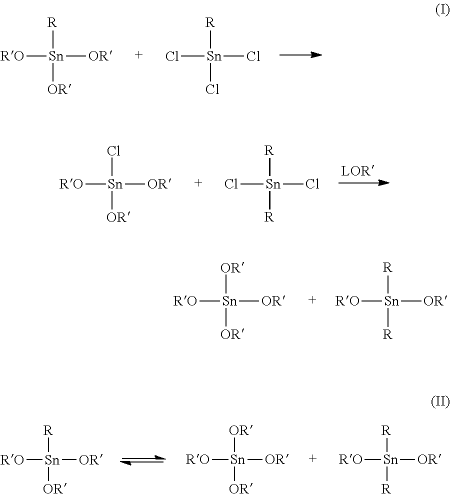

The ability to prepare and isolate tin compounds containing a fluoroalkoxy substituent and having desired high purity levels has not previously been reported. Such high purity tin compounds would be very attractive for use in the microelectronic industry.

### SUMMARY OF THE INVENTION

In one embodiment, aspects of the disclosure relate to a monoorgano tin compound having formula (1) having a purity of at least about 95 mol % and containing less than about 5 mol % of a diorgano tin compound having formula (2):

R′SnX₃ (1)

R′₂SnX₂ (2)

wherein R′ is an optionally substituted organic substituent having about 1 to about 20 carbon atoms and each X is independently OR_{f}, wherein R_{f} is a fluorinated organic substituent having about 1 to about 20 carbon atoms.

In a second embodiment, aspects of the disclosure relate to method of synthesizing a monoorgano tin compound having formula (1)

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting a compound containing an R′ group with a compound having formula SnX₄.

In a further embodiment, aspects of the disclosure relate to a method of synthesizing a monoorgano tin compound having formula (1)

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting an R′SnY₃ compound with a compound containing an OR_{f} group, wherein Y is a halogen atom, an alkoxy group, or a dialkylamino group.

A further embodiment relates to a method of synthesizing a monoorgano tin compound having formula (1)

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising:
(a) reacting a metal compound comprising an alkali metal M and a ligand X with a compound having formula SnY₂ to form a compound having formula MSnX₃; and (b) reacting the compound having formula MSnX₃ with a compound R′Z, wherein Z is a halogen atom and Y is a halogen atom, an alkoxy group, or a dialkylamino group.

Aspects of the disclosure further relate to monoorgano tin compound having formula (6) having a purity of at least about 95 mol % and containing less than about 5 mol % of a diorgano tin compound having formula (7):

R″Sn(NR₂)₃ (6)

R″₂Sn(NR₂)₂ (7)

wherein R″ is a linear or branched unsaturated hydrocarbon group having about 2 to about 20 carbon atoms and R is a linear or branched alkyl group having about 1 to about 10 carbon atoms.

Further aspects of the disclosure relate to a method of synthesizing a monoorgano tin compound having formula (6):

R″Sn(NR₂)₃ (6)

the method comprising reacting a R″Sn(OR_{f})₃ compound with a compound containing a NR₂ group, wherein R″ is a linear or branched unsaturated hydrocarbon group having about 2 to about 20 carbon atoms, R_{f} is a fluorinated organic substituent having about 1 to about 20 carbon atoms, and R is a linear or branched alkyl group having about 1 to about 10 carbon atoms.

Additional aspects of the disclosure relate to an organotin compound having formula (3):

R′SnO_{(3/2-x/2)}(OH)ₓ (8)

wherein the compound having formula (8) is obtained by hydrolysis of a compound having formula (1):

R′SnX₃ (1)

wherein 0<x≤3, R′ is an optionally substituted organic substituent having about 2 to about 20 carbon atoms and each X is independently OR_{f}, wherein R_{f} is a fluorinated organic substituent having about 1 to about 20 carbon atoms.

Finally, additional aspects of the disclosure relate to an organotin compound having formula (9), wherein the compound having formula (9) is obtained by hydrolysis of a compound having formula (6):

R″Sn(NR₂)₃ (6)

R″SnO_{(3/2-y/2)}(OH)_{y} (9)

wherein 0<y≤3, R″ is a linear or branched unsaturated hydrocarbon group having about 2 to about 20 carbon atoms and R is a linear or branched alkyl group having about 1 to about 10 carbon atoms.

Advantageous refinements of the invention, which can be implemented alone or in combination, are specified in the dependent claims.

In summary, the following embodiments are proposed as particularly preferred in the scope of the present invention:

Embodiment 1: A monoorgano tin compound having formula (1) having a purity of at least about 95 mol % and containing less than about 5 mol % of a diorgano tin compound having formula (2):

R′SnX₃ (1)

R′₂SnX₂ (2)

wherein R′ is an optionally substituted organic substituent having about 1 to about 20 carbon atoms and each X is independently OR_{f}, wherein R_{f} is a fluorinated organic substituent having about 1 to about 20 carbon atoms.

Embodiment 2: The monoorgano tin compound according to Embodiment 1, wherein R′ is substituted with at least one halogen, oxygen, and/or nitrogen atom.

Embodiment 3: The monoorgano tin compound according to Embodiment 1 or 2, wherein a total content of a tin compound having formula (3) is less than about 5 mol %:

R′₃SnX (3).

Embodiment 4: The monoorgano tin compound according to any of Embodiments 1-3, wherein a total content of a tin compound having formula (4) is less than about 5 mol %

R′₄Sn (4).

Embodiment 5: The monoorgano tin compound according to any of Embodiments 1-4, wherein a total content of a tin compound having formula (5) is less than about 5 mol %:

SnX₄ (5).

Embodiment 6: The monoorgano tin compound according to any of Embodiments 1-5, wherein R_{f} is a linear or branched fluorinated alkyl, aryl, or aralkyl group.

Embodiment 7: The monoorgano tin compound according to any of Embodiments 1-6, wherein R_{f} is a linear or branched fluorinated alkyl group.

Embodiment 8: The monoorgano tin compound according to any of Embodiments 1-7, wherein R_{f} is selected from:

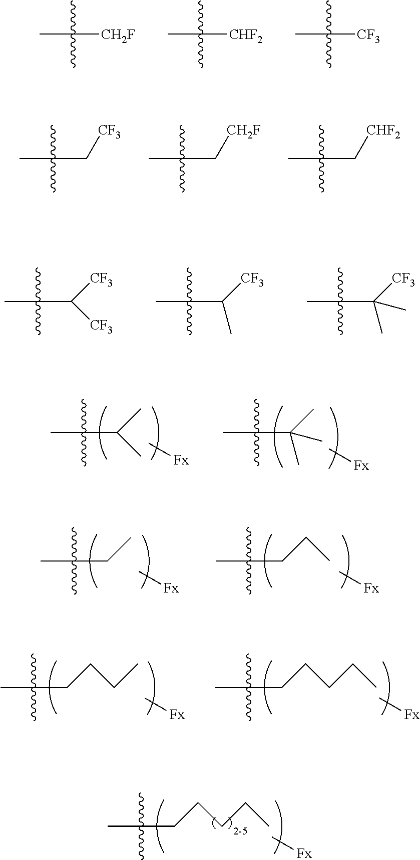

wherein Fx indicates that at least one hydrogen atom in brackets is replaced by one or more fluorine atoms.

Embodiment 9: The monoorgano tin compound according to any of Embodiments 1-8, wherein R_{f} contains at least three fluorine atoms.

Embodiment 10: A method of synthesizing a monoorgano tin compound having formula (1):

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting a compound containing an R group with a compound having formula (5):

SnX₄ (5).

Embodiment 11: The method according to Embodiment 10, wherein the compound containing an R′ group is a compound having formula R′MgZ, wherein Z is a halogen atom.

Embodiment 12: A method of synthesizing a monoorgano tin compound having formula (1):

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting an R′SnY₃ compound with a compound containing an OR_{f} group, wherein Y is a halogen atom, an alkoxy group, or a dialkylamino group.

Embodiment 13: The method according to Embodiment 12, wherein Y is a dialkylamino group.

Embodiment 14: The method according to Embodiment 12 or 13, wherein R′SnY₃ is prepared by reacting an R′₄Sn compound with a SnY₄ compound.

Embodiment 15: A method of synthesizing a monoorgano tin compound having formula (1):

R′SnX₃ (1)

wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising:
(a) reacting a metal compound comprising an alkali metal M and a ligand X with a compound having formula SnY₂ to form a compound having formula MSnX₃; and
(b) reacting the compound having formula MSnX₃ with a compound R′Z, wherein Z is a halogen atom and Y is a halogen atom, an alkoxy group, or a dialkylamino group.

Embodiment 16: The method according to any of Embodiments 10-15, wherein the reaction is performed in a solvent containing greater than about 50% by volume of an aliphatic hydrocarbon solvent and/or an aromatic hydrocarbon solvent.

Embodiment 17: The method according to Embodiment 16, wherein the solvent is dehydrated prior to performing the reaction.

Embodiment 18: The method according to any of Embodiments 10-17, further comprising at least one purification step substantially without light exposure.

Embodiment 19: The method according to Embodiment 18, wherein the at least one purification step comprises fractional distillation.

Embodiment 20: The method according to any of Embodiments 10-19, wherein the reaction is performed substantially without light exposure.

Embodiment 21: A method of storing a sample of the monoorgano tin compound having formula (1) according to any of Embodiments 1 to 9, the method comprising storing the sample of the monoorgano tin compound having formula (1) substantively without light exposure and at a temperature of less than about 30° C.

Embodiment 22: The method according to Embodiment 21, wherein the sample of the monoorgano tin compound having formula (1) is stored for about three days to about one year.

Embodiment 23: The method according to Embodiment 21 or 22, wherein the sample of the monoorgano tin compound undergoes substantively no decomposition after a storage time of about three days to about one year.

Embodiment 24: The method according to any of Embodiments 21 to 23, comprising storing the compound having formula (1) in a container in an inert atmosphere.

Embodiment 25: The method according to any of Embodiments 21 to 24, comprising storing the compound having formula (1) in a container with gas barrier properties.

Embodiment 26: A monoorgano tin compound having formula (6) having a purity of at least about 95 mol % and containing less than about 5 mol % of a diorgano tin compound having formula (7):

R″Sn(NR₂)₃ (6)

R″₂Sn(NR₂)₂ (7)

wherein R″ is a linear or branched unsaturated hydrocarbon group having about 2 to about 20 carbon atoms and R is a linear or branched alkyl group having about 1 to about 10 carbon atoms.

Embodiment 27: The monoorgano tin compound having formula (6) according to Embodiment 26, wherein R″ is an allyl group and R is a methyl group.

Embodiment 28: A method of synthesizing a monoorgano tin compound having formula (6):

R″Sn(NR₂)₃ (6)

the method comprising reacting a R″Sn(OR_{f})₃ compound with a compound containing a NR₂ group, wherein R″ is a linear or branched unsaturated hydrocarbon group having about 2 to about 20 carbon atoms, R_{f} is a fluorinated organic substituent having about 1 to about 20 carbon atoms, and R is a linear or branched alkyl group having about 1 to about 10 carbon atoms.

Embodiment 29: An organotin compound having formula (8):

R′SnO_{(3/2-x/2)}(OH)ₓ (8)

wherein the compound having formula (8) is obtained by hydrolysis of a compound having formula (1):

R′SnX₃ (1)

wherein 0<x≤3, R′ is an optionally substituted organic substituent having about 2 to about 20 carbon atoms and each X is independently OR_{f}, wherein R_{f} is a fluorinated organic substituent having about 1 to about 20 carbon atoms.

Embodiment 30: An organotin compound having formula (9), wherein the compound having formula (9) is obtained by hydrolysis of a compound having formula (6):

R″Sn(NR₂)₃ (6)

R″SnO_{(3/2-y/2)}(OH)_{y} (9)

wherein 0<y≤3, R″ is a linear or branched unsaturated hydrocarbon group having about 2 to about 20 carbon atoms and R is a linear or branched alkyl group having about 1 to about 10 carbon atoms.

Embodiment 31: A solution comprising the organotin compound having formula (8) and/or (9) according to Embodiment 29 or 30 and an organic solvent.

Embodiment 32: A film comprising the organotin compound having formula (8) and/or (9) according to Embodiment 29 or 30.

Embodiment 33: The monoorgano tin compound according to any of Embodiments 1 to 9, wherein R′ is a linear or branched alkyl group.

Embodiment 34: A method of synthesizing a tin compound having formula (8)

R′SnO_{(3/2-x/2)}(OH)ₓ (8)

the method comprising hydrolyzing a compound having formula (1):

R′SnX₃ (1)

wherein 0<x≤3, R′ is an optionally substituted organic substituent having about 2 to about 20 carbon atoms and each X is independently OR_{f}, wherein R_{f} is a fluorinated organic substituent having about 1 to about 20 carbon atoms.

Embodiment 35: A method of synthesizing a tin compound having formula (9)

R″SnO_{(3/2-y/2)}(OH)_{y} (9)

the method comprising hydrolyzing a compound having formula (6):

R″Sn(NR₂)₃ (6)

wherein 0<y≤3, R″ is a linear or branched unsaturated hydrocarbon group having about 2 to about 20 carbon atoms and R is a linear or branched alkyl group having about 1 to about 10 carbon atoms.

### DETAILED DESCRIPTION OF THE INVENTION

According to one aspect of the disclosure, provided are monoorgano tin compounds having formula (1). For the purposes of this disclosure, the term “monoorgano” refers to an optionally substituted organic substituent having about 1 to about 20 carbon atoms. The compounds having formula (1) preferably have a purity of at least about 95 mol % and preferably contain no more than about 5 mol % diorgano tin compounds having formula (2) relative to the total amount of tin, preferably no more than about 4 mol %, no more than about 3 mol %, no more than about 2 mol %, more preferably no more than about 1 mol %, even more preferably no more than about 0.5 mol %, even more preferably no more than about 0.1 mol %.

R′SnX₃ (1)

R′₂SnX₂ (2)

In formulas (1) and (2), R′ is an optionally substituted organic substituent having about 1 to about 20 carbon atoms and each X is independently OR_{f}, wherein R_{f} is a fluorinated organic substituent having about 1 to about 20 carbon atoms. More specifically, R′ may be a linear or branched, optionally substituted, hydrocarbon group having about 1 to about 20 carbon atoms, preferably about 2 to about 10 carbon atoms, more preferably about 2 to about 7 carbon atoms; each R′ is optionally substituted with one or more halogen, oxygen, and/or nitrogen atoms. R′ may include saturated and unsaturated hydrocarbon groups, such as alkyl, alkenyl, and alkynyl groups, including linear, branched, and cyclic groups, as well as aromatic groups, such as aryl and aralkyl (such as, for example, benzyl).

It has been found that the addition of CF₃ groups to the alkoxide ligand may improve the volatility/vapor pressure of the resulting tin compounds in part because the fluorine atoms provide an increasing amount of intermolecular repulsion due to their high electronegativity relative to carbon. In addition, fluorine has reduced polarizability (as compared to hydrogen), which causes fluorinated ligands to have less intermolecular attractive interactions. Extending this concept, separation of unwanted by-products may also be simplified as the vapor pressure difference between [CF₃(CH₃)₂CO]₂SnR₂, [CF₃(CH₃)₂CO]₃SnR, and [CF₃(CH₃)₂CO]₄Sn would be greater than what is observed for the related tert-butoxide or amide derivatives. This means that high purity tin compounds would be obtained by distillation at a relatively low temperature or simpler distillation operation; this is particularly effective for tin compounds containing R′ substituents which are unstable under higher temperature conditions and/or longer distillation times.

In general, fluorinated alkoxides are weaker donors/bases than standard alkoxides due to the electronegativity of the fluorine atoms. In addition to stability towards residual moisture, the weaker donation to tin from the fluorinated alkoxides may also serve to strengthen the tin-carbon bond and thus provide more stable tin alkenyl or alkynyl complexes. The fluorinated alkoxide is also much less likely to attack the double bond of the allyl group as it is less nucleophilic than an amide ligand. It is therefore effective for such groups to be combined with an R′ having unsaturated organic substituents (such as alkenyl or alkynyl) that may optionally be substituted with fluorine. On the other hand, a linear or branched alkyl group is preferred for R′ in terms of compound stability, and a secondary or tertiary alkyl group is even more preferred in terms of sensitivity.

These tin compounds are less sensitive to residual moisture than the related alkoxy tin complexes because of the stability described above and the hydrophobicity of fluorine atoms. The stability in the residual moisture is advantageous for the stable production and storage of the tin compounds. When used for EUV resist materials, they should still react with water under CVD conditions or wet coating process conditions to deposit tin oxides.

In view of these properties of the tin compounds containing fluorinated alkoxide ligands, these compounds are useful not only for use as a resist material, but also for use as a high purity and stable intermediate for other mono alkyl tin compounds, especially those that are difficult to synthesize by known procedures, using an exchange reaction of the fluorinated alkoxy ligand with other ligands. This aspect of the disclosure is discussed in more detail below.

Each R_{f} is independently a fluorinated organic substituent having about 1 to about 20 carbon atoms, such as a linear or branched (primary, secondary, or tertiary) alkyl, aryl, or aralkyl group having about 1 to about 20 carbon atoms, preferably about 1 to about 5 carbon atoms, more preferably 1 to about 4 carbon atoms, such as, without limitation, fluorinated methyl, ethyl, n-propyl, isopropyl, n-butyl, isobutyl, t-butyl, etc. In preferred embodiments, R_{f} contains at least three fluorine atoms to maximize the benefits of fluorinated alkoxides, discussed above. On the other hand, there are cases where the number of fluorine atoms should be reduced to two or one, particularly when considering environmental regulations and legal compliance regarding fluorine materials. Tertiary alkoxides are also preferred because they enhance the stability of the tin alkoxide compound and may inhibit the oligomerization and aggregation of tin alkoxide compound.

Preferred R_{f} substituents include the following, where the wavy line indicates a point of attachment to the O atom. Groups marked with Fx indicate that the hydrogen atom in brackets is replaced by one or more fluorine atoms, that is, Fx indicates that at least one hydrogen atom in brackets is replaced by one or more fluorine atoms.

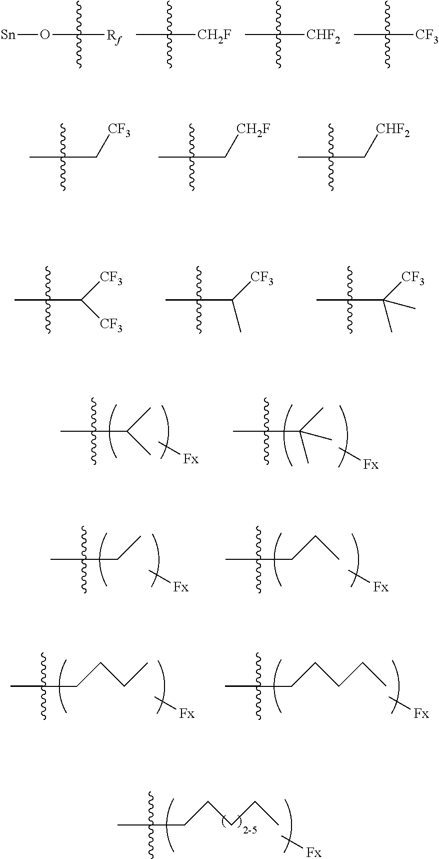

Among these OR_{f} substituents, 2,2,2-trifluoroethoxy, 1,1,1,3,3,3-hexafluoro-2-propoxy, and 1,1,1-trifluoro-2-methylpropan-2-yl)oxy are preferred in terms of commercial availability and price. 1,1,1-trifluoro-2-methylpropan-2-yl is more preferred in terms of stability because it contains a tertiary alkoxy group.

Unless otherwise stated, any numerical value herein is to be understood as being modified in all instances by the term “about.” Thus, a numerical value typically includes ±10% of the recited value. For example, the recitation of a temperature such as “10° C.” or “about 10° C.” includes 9° C. and 11° C. and all temperatures therebetween.

All numerical ranges expressed in this disclosure expressly encompass all possible subranges, all individual numerical values within that range, including integers within such ranges and fractions and decimal amounts of the values unless the context clearly indicates otherwise. Accordingly, the content of the compound having formula (2) is in some embodiments preferably less than about 5 mol %, less than about 4 mol %, less than about 3 mol %, less than about 2 mol %, less than about 1 mol %, less than about 0.9 mol %, less than about 0.8 mol %, less than about 0.7 mol %, less than about 0.6 mol %, less than about 0.5 mol %, less than about 0.4 mol %, less than about 0.3 mol %, less than about 0.2 mol %, less than about 0.1 mol %, less than about 0.05 mol %, less than about 0.04 mol %, less than about 0.03 mol %, less than about 0.02 mol %, less than about 0.01 mol %, or non-detectable by ¹¹⁹Sn NMR, that is, the compound having formula (2) is in some embodiments undetectable in a sample of the compound having formula (1).

In some embodiments, the content (that is, a total content) of a compound having formula (3) is less than about 5 mol %, less than about 3 mol %, less than about 2 mol %, less than about 1 mol %, less than about 0.7 mol %, less than about 0.5 mol %, or less than about 0.1 mol %:

R′₃SnX (3).

In some embodiments, the content (that is, a total content) of a compound having formula (4) is less than about 5 mol %, less than about 3 mol %, less than about 2 mol %, less than about 1 mol %, less than about 0.7 mol %, less than about 0.5 mol %, or less than about 0.1 mol %:

R′₄Sn (4).

In some embodiments, the content (that is, a total content) of a compound having formula (5) is less than about 5 mol %, less than about 3 mol %, less than about 2 mol %, less than about 1 mol %, less than about 0.7 mol %, less than about 0.5 mol %, or less than about 0.1 mol %:

SnX₄ (5).

The organometallic tin compounds having formula (1) may be used for the formation of high-resolution EUV lithography patterning precursors and are attractive due to their electron density, Sn—C bond strength, and radical formation, as well as the potential to reduce EUV dose time.

Exemplary compounds having formula (1) according to aspects of the disclosure include, without limitation, those containing the following R′ substituents, where the wavy line indicates a point of attachment to the Sn atom. In these formulas, R^{a}, R^{b}, and R^{c} are each independently hydrogen or a saturated hydrocarbon group having about 1 to about 5 carbon atoms.

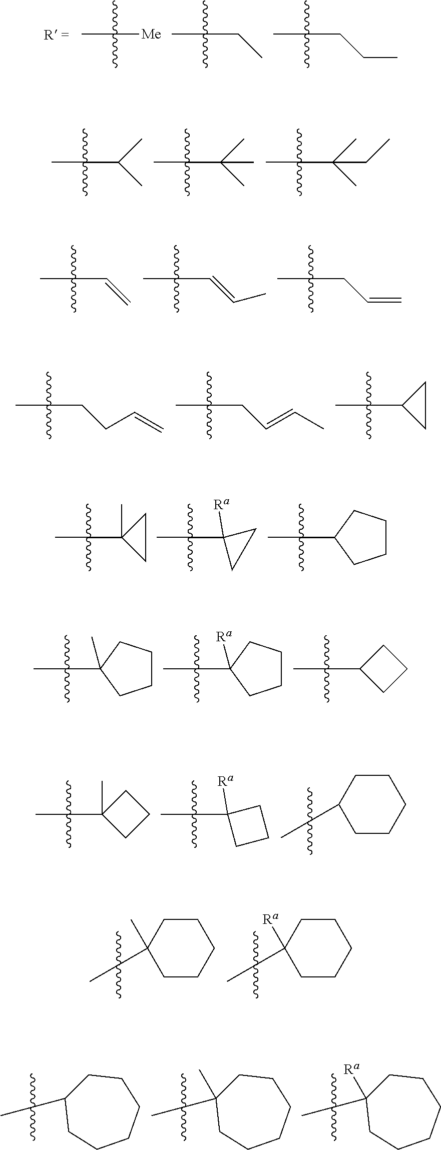

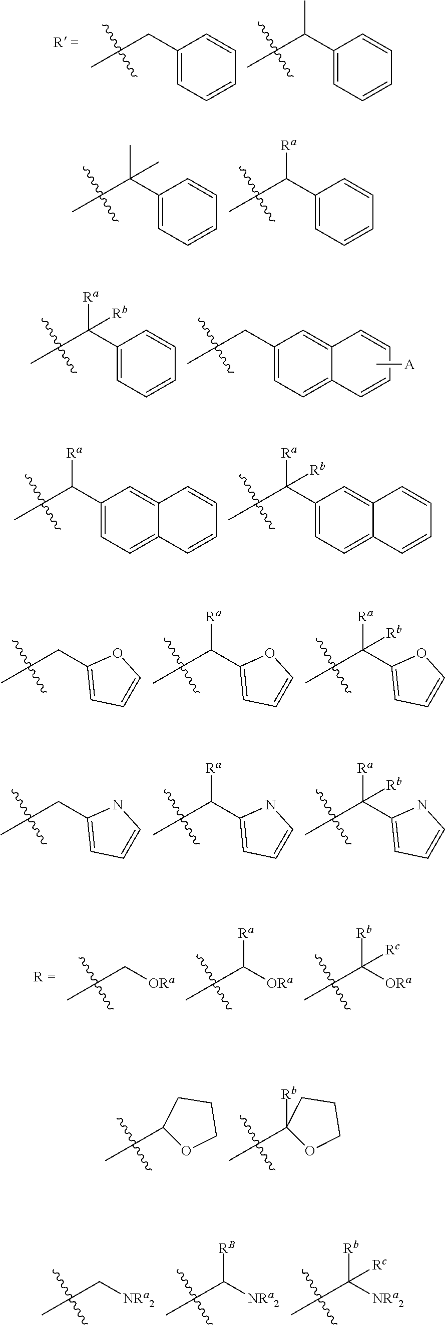

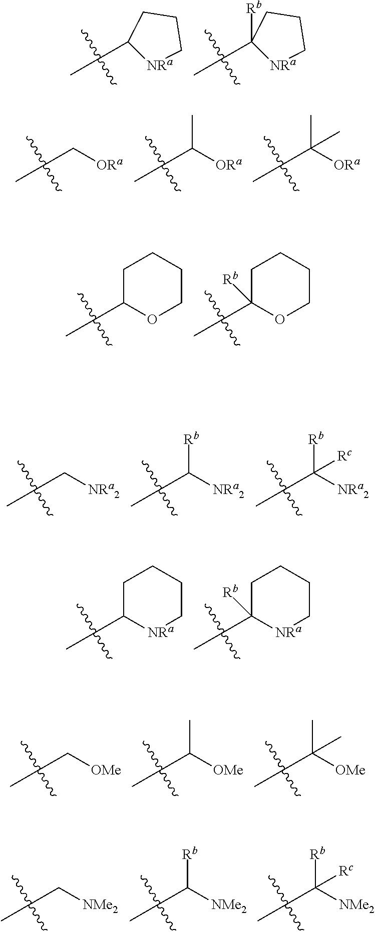

Exemplary tin compounds having formula (1) include, without limitation, isopropyl tris(2,2,2-trifluoroethoxy)tin, methyl tris(2,2,2-trifluoroethoxy)tin, ethyl tris(2,2,2-trifluoroethoxy)tin, n-butyl tris(2,2,2-trifluoroethoxy)tin, t-butyl tris(2,2,2-trifluoroethoxy)tin, t-amyl tris(2,2,2-trifluoroethoxy)tin, vinyl tris(2,2,2-trifluoroethoxy)tin, allyl tris(2,2,2-trifluoroethoxy)tin, 3-butenyl tris(2,2,2-trifluoroethoxy)tin, benzyl tris(2,2,2-trifluoroethoxy)tin, 1-methyl-benzyl tris(2,2,2-trifluoroethoxy)tin[or 2-phenyl-2-propyl tris(2,2,2-trifluoroethoxy)tin], isopropyl tris(1,1,1,3,3,3-hexafluoro-2-propoxy)tin, methyl tris(1,1,1,3,3,3-hexafluoro-2-propoxy)tin, ethyl tris(1,1,1,3,3,3-hexafluoro-2-propoxy)tin, n-butyl tris(1,1,1,3,3,3-hexafluoro-2-propoxy)tin, t-butyl tris(1,1,1,3,3,3-hexafluoro-2-propoxy)tin, t-amyl tris(1,1,1,3,3,3-hexafluoro-2-propoxy)tin, vinyl tris(1,1,1,3,3,3-hexafluoro-2-propoxy)tin, allyl tris(1,1,1,3,3,3-hexafluoro-2-propoxy)tin, 3-butenyl tris(1,1,1,3,3,3-hexafluoro-2-propoxy)tin, benzyl tris(1,1,1,3,3,3-hexafluoro-2-propoxy)tin, 1-methyl-benzyl tris(1,1,1,3,3,3-hexafluoro-2-propoxy)tin[or 2-phenyl-2-propyl tris(1,1,1,3,3,3-hexafluoro-2-propoxy)tin], isopropyl tris((1,1,1-trifluoro-2-methylpropan-2-yl)oxy)tin, methyl tris((1,1,1-trifluoro-2-methylpropan-2-yl)oxy)tin, ethyl tris((1,1,1-trifluoro-2-methylpropan-2-yl)oxy)tin, n-butyl tris((1,1,1-trifluoro-2-methylpropan-2-yl)oxy)tin, t-butyl tris((1,1,1-trifluoro-2-methylpropan-2-yl)oxy)tin, t-amyl tris((1,1,1-trifluoro-2-methylpropan-2-yl)oxy)tin, vinyl tris((1,1,1-trifluoro-2-methylpropan-2-yl)oxy)tin, allyl tris((1,1,1-trifluoro-2-methylpropan-2-yl)oxy)tin, 3-butenyl tris((1,1,1-trifluoro-2-methylpropan-2-yl)oxy)tin, benzyl tris((1,1,1-trifluoro-2-methylpropan-2-yl)oxy)tin, 1-methyl-benzyl tris((1,1,1-trifluoro-2-methylpropan-2-yl)oxy)tin[or 2-phenyl-2-propyl tris((1,1,1-trifluoro-2-methylpropan-2-yl)oxy)tin], isopropyl tris(2,2,2-trifluoroethoxy)tin, and isopropyl tris(1,1,1,3,3,3-hexafluoro-2-propoxy)tin.

### Methods of Synthesis

Aspects of the disclosure additionally relate to methods for synthesizing the high purity tin compounds having formula (1) as described above which are suitable for use in the microelectronic industry and which preferably contain low levels of diorgano tin compounds having formula (2). One method involves the reaction of a compound containing an R′ group with a compound having formula SnX₄. A second method involves the reaction of a compound containing an OR_{f} group with a compound having formula R′SnY₃, where Y is a halogen, atom, an alkoxy group, or a dialkylamino group. A third method involves first reacting a metal compound containing an alkali metal M and a ligand X with a compound having formula SnY₂ (where Y is a halogen, atom, an alkoxy group, or a dialkylamino group) to form a compound having formula MSnX₃, followed by reacting the compound having formula MSnX₃ with a compound R′Z, where Z is a halogen atom. These methods will be described in further detail below. If desired, following initial purification, the level of diorgano tin compound and other minor impurities may be further reduced using fractional distillation.

For the compounds described herein, it is possible to improve volatility/vapor pressure and distill and purify at lower temperatures. Therefore, even Sn compounds with unstable functional groups may be obtained with high purity by low-temperature distillation and other operations. The obtained fluorine-containing alkoxy ligands may be converted to other substituents by known methods, i.e., they can be used as synthetic raw materials for tin compounds with other substituents (e.g., NR₂) of high purity.

¹¹⁹Sn NMR spectroscopy is ideally suited to the quantitative analysis of monoorgano tin compounds due to its high sensitivity to small structural changes and large spectral range of 6500 ppm (see Davies et al., Eds.; Tin Chemistry: Fundamentals, Frontiers, and Applications; Wiley (2008)). This allows for easy identification and quantification of monoorgano tin compounds and their impurities because ¹¹⁹Sn resonances are highly resolved. ¹¹⁹Sn NMR suffers from reduced sensitivity compared to other analytical methods such as GC, HPLC, or ¹H NMR. To improve sensitivity, monoorgano tin compounds are analyzed without dilution, and a large number of spectral acquisitions (2000+) are acquired to measure the low levels of impurities described in this work. Using this approach, detection limits of as low as 0.1 mol % diorgano tin dialkoxides can be achieved.

The ¹¹⁹Sn NMR data described herein were obtained using a method similar to the relative purity method described in J. Med. Chem. (57, 22, 9220-9231 (2014)). ¹¹⁹Sn NMR spectra were acquired using inverse-gated ¹H decoupling with a 400 pulse, one second relaxation delay, and sufficient scans to achieve the required sensitivity. Samples were prepared without dilution in deuterated solvent. Quantitation was performed by integrating all peaks in the spectrum and setting the total peak area to 100. Each peak in the spectrum represents a distinct tin compound and the area of each peak represents the concentration or purity of that compound in mol %.

A first method of synthesizing a monoorgano tin compound having formula (1) according to aspects of the disclosure comprises reacting a compound containing an R′ group with a compound having formula SnX₄, where R′ and X have been previously defined. An exemplary compound containing an R′ group is a Grignard reagent, R′MgZ, where Z is a halogen atom such as the presently preferred bromine. Other compounds containing an R′ group include, without limitation, R′Li, R′Na, R′K, R′ZnZ, R′₂Zn, R′₃Al, and mixtures thereof. An exemplary general reaction scheme for this method employing a Grignard reagent is:

SnX₄+R′MgZ→R′SnX₃

This method is preferable when R′ contains tertiary alkyl group such as t-butyl, because the overreaction to dialkyl compounds is suppressed by the large steric hindrance of the tertiary alkyl group.

Preferably, the method involves reacting the compound containing an R′ group and the SnX₄ compound in an appropriate solvent. Preferred solvents include aliphatic hydrocarbons (such as, but not limited to, hexane, hexanes, heptane, and cyclohexane), aromatic hydrocarbons (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of compounds containing an R′ group (such as R′MgZ) in these types of solvents. It is also preferable to use mixtures of these solvents, such as mixtures of hydrocarbons and/or aromatics with ethers to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 40° C., about 25° C., about 20° C., or the most preferred upper limit of about 10° C., as well as all intervening temperatures. Thus, the preferred temperature range is about 0° C. to about 10° C. In other embodiments, however, the reaction is preferably performed at room temperature. If the temperature is too low, the reaction rate will be too slow, whereas if the temperature is too high, byproducts will be produced.

A solution containing the compound containing the R′ group preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %.

It has been found that such dilute concentrations provide effective control of reaction temperature or solubility of the R′ compound. On the other hand, the productivity is lower in dilute concentrations in industrial conditions.

The concentration of the SnX₄ compound in solution is preferably up to about up to about 30 wt %, more preferably up to about 20 wt %, most preferably up to about 15 wt %. The concentration is preferably greater than about 1 wt %, greater than about 2 wt %, greater than about 3 wt %, even more preferably greater than about 5 wt %.

However, the appropriate solvent and concentrations of the reactants may be determined by routine experimentation.

The molar amount of the R′ group-containing compound relative to SnX₄ is preferably greater than about 1.0 equivalents, greater than about 1.1 equivalents, greater than about 1.2 equivalents, greater than about 1.3 equivalents, or greater than about 1.4 equivalents. The molar amount of the R′ group-containing compound relative to SnX₄ is preferably less than about 2.0 equivalents, less than about 1.8 equivalents, less than about 1.6 equivalents, more preferably less than about 1.4 equivalents. If the relative amount of the R′ group-containing compound is too low, starting materials (SnX₄) may remain. Further, the reaction speed may be too low and the amount of impurities may increase due to side reactions, such as redistribution. If the relative amount of the R′ group-containing compound is too high, over reaction may occur and poly alkylated byproducts (such as R′₂SnX₂, R′₃SnX, and R′₄Sn) may form. When the boiling point of R′SnX₃ is close to the boiling points of R′₂SnX₂ and SnX₄, it is especially important to reduce the concentrations of R′₂SnX₂ and SnX₄ because of the difficulty of purification by distillation.

Following the reaction of the two components, the reaction mixture is worked up and purified using methods well known in the art to produce the compound having formula (1).

An exemplary reaction scheme for this method is shown here:

Sn(OR_{f})₄+R′MgZ→R′Sn(OR_{f})₃

Sn(OR_{f})₄+R′Li→R′Sn(OR_{f})₃

A second method of synthesizing a monoorgano tin compound having formula (1) according to aspects of the disclosure comprises reacting a compound containing an OR_{f} group with a compound having formula R′SnY₃, where Y is a halogen atom, alkoxy group, or dialkyl amino group. Preferred halogen atoms include chlorine, bromine, and fluorine. Most preferably, the R′SnY₃ compound is R′SnC1₃ or R′Sn(NMe₂)₃. The R′SnY₃ compound may be purchased commercially or prepared, such as, for example, by the redistribution reaction of R′₄Sn and SnY₄ (such as reacting R′₄Sn with SnCl₄ to produce R′SnCl₃). This method is preferable when high purity R′SnCl₃ or R′Sn(NMe₂)₃ can be obtained and are stable under the reaction conditions.

Exemplary reaction schemes for this method include:

3R_{f}OH+R′Sn(NMe₂)₃→R′Sn(OR_{f})₃

3LiOR_{f}+R′SnCl₃→R′Sn(OR_{f})₃

Exemplary compounds containing an OR_{f} group include HOR_{f}, LiOR_{f}, NaOR_{f}, KOR_{f}, Mg(OR_{f})₂, Zn(OR_{f})₂, Al(OR_{f})₃. Among these compounds, reagents containing Li, Na, and K are preferred in terms of reactivity; HOR_{f} is preferred when Y in R′SnY₃ is NR₂.

Preferably, the method involves reacting the compound containing an OR_{f} group and the R′SnY₃ compound in an appropriate solvent. Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of compounds containing an OR_{f} group in these types of solvents. Alcohols (MeOH, EtOH, especially ROH) are also preferred solvents for compounds containing an OR_{f} group. It is also preferable to use mixtures of these solvents, such as mixtures of hydrocarbons and/or aromatics with ethers and/or alcohols to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 40° C., about 25° C., about 20° C., or the most preferred upper limit of about 10° C. as well as all intervening temperatures. Thus, the preferred temperature range is about 0° C. to about 10° C. If the temperature is too low, the reaction rate will be too slow, whereas if the temperature is too high, byproducts will be produced.

A solution containing the OR_{f} compound preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %.

It has been found that such dilute concentrations provide effective control of reaction temperature or solubility of the OR_{f} compound. On the other hand, the productivity is lower in dilute concentrations in industrial conditions.

The concentration of the R′SnY₃ compound in solution is preferably up to about up to about 30 wt %, more preferably up to about 20 wt %, most preferably up to about 15 wt %. The concentration is preferably greater than about 1 wt %, greater than about 2 wt %, greater than about 3 wt %, even more preferably greater than about 5 wt %. However, the appropriate solvent and concentrations of the reactants may be determined by routine experimentation.

The molar amount of the OR_{f} compound relative to R′SnY₃ is preferably greater than about 3.0 equivalents, greater than about 3.05 equivalents, greater than about 3.09 equivalents, greater than about 3.10 equivalents, or greater than about 3.15 equivalents. If the relative amount of the OR_{f} compound is too low, the reaction speed may be too low and the amount of impurities may increase due to side reactions such as redistribution.

Following reaction of the two components, the reaction mixture is worked up and purified using methods well known in the art to produce the compound having formula (1).

A third method of synthesizing a monoorgano tin compound having formula (1) according to aspects of the disclosure comprises first reacting a metal compound containing an alkali metal M and a ligand X (OR_{f}) with a compound having formula SnY₂ to form a compound having formula MSnX₃, where Y is a halogen atom, an alkoxy group, or a dialkylamino group, followed by reacting the compound having formula MSnX₃ with a compound R′Z, where Z is a halogen atom. Preferred halogen atoms include chlorine, bromine, and fluorine. Most preferably, the SnY₂ compound is SnCl₂ in terms of reactivity and stability. Preferably the compound containing M and X is selected from LiOR_{f}, NaOR_{f}, and KOR_{f}. Preferably MSnX₃ is selected from LiSn(OR_{f})₃, NaSn(OR_{f})₃, and KSn(OR_{f})₃. Among these compounds, LiSn(OR_{f})₃ is preferred for stability in preparation.

An exemplary reaction scheme for this method is:

3LiOR_{f}+SnCl₂→LiSn(OR_{f})₃

LiSn(OR_{f})₃+R′Z→R′Sn(OR_{f})₃

Preferably, the first step involves reacting the compound containing M and X and the SnY₂ compound in an appropriate solvent. Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Most preferred solvents are ethers, such as THF to prepare MSnX₃ which is an Sn anion species and stable under coordination by ether solvent.

Lower preferred temperatures for the reaction are about −78° C., about −40° C., about −20° C., about −10° C., most preferably about 0° C., as well as all intervening temperatures, and the upper limit of the reaction temperature is preferably about 100° C., about 90° C., or about 80° C., as well as all intervening temperatures. Thus, the preferred temperature range is about 0° C. to about 80° C. If the temperature is too low, the reaction rate will be too slow, whereas if the temperature is too high, byproducts will be produced.

A solution containing the compound containing M and X preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature or solubility of the compound containing M and X. On the other hand, the productivity is lower in dilute condition in industrial conditions.

The molar amount of the compound containing M and X relative to the amount of SnY₂ is preferably greater than about 3.0 equivalents, greater than about 3.05 equivalents, greater than about 3.09 equivalents, greater than about 3.10 equivalents, or greater than about 3.15 equivalents. If the relative amount is too low, the reaction speed may be too low and the amount of impurities may increase due to side reactions.

Preferably, the second step involves reacting the MSnX₃ compound and the R′Z compound in an appropriate solvent. Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of the reactants in these types of solvents. It is also preferable to use mixtures of these solvents, such as mixtures of hydrocarbons and/or aromatics with ethers to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 100° C., about 90° C., or the most preferred upper limit of about 80° C., as well as all intervening temperatures. Thus, the preferred temperature range is about 0° C. to about 80° C. If the temperature is too low, the reaction rate will be too slow, whereas if the temperature is too high, byproducts will be produced.

A solution containing the R′Z compound preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %. It has been found that such dilute concentrations provide effective control of reaction temperature. On the other hand, the productivity is lower in dilute condition in industrial conditions.

The molar amount of the R′Z compound relative to MSnX₃ is preferably greater than about 1.0 equivalents, greater than about 1.1 equivalents, greater than about 1.2 equivalents, or greater than about 1.25 equivalents. If the relative amount is too low, the reaction speed may be too low and the amount of impurities may increase due to side reactions.

Following reaction of the two components, the reaction mixture is worked up and purified using methods well known in the art to produce the compound having formula (1).

In all of the methods described herein, the reactants are preferably added in a dropwise fashion to control the exothermic reaction and the method steps are preferably performed in an inert atmosphere, such as nitrogen or argon. The reactants may be added neat (without solvent) and it is preferable to add the reactants quickly to achieve high productivity. However, it is preferable to perform the reactions in solvent to control the exothermic reaction. Appropriate solvents include, as previously explained, without limitation, hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. In some cases, most preferred solvents are ethers, such as THF.

After completing the reaction, the reaction mixtures are allowed to slowly warm to room temperature, such as over a period of about four hours, and then stirred for an additional period of time at room temperature, such as for about two to four hours. The reaction mixture is then filtered, such as through celite, to remove the metal byproduct. Other means of filtration which are known in the art may also be employed. The resulting salt is then rinsed, such as with anhydrous hexanes, and the solvent is removed under reduced pressure by means known in the art to produce a crude product.

In all three of the methods described above, the crude product is distilled, such as at less than about 10 torr, preferably less than about 0.5 torr to yield the desired product containing the compound having formula (1) having a purity of greater than about 95 mol % and preferably no more than about 5 mol % of the diorgano tin compound having formula (2). The appropriate distillation conditions may be determined on a case-by-case basis depending on the desired product using routine experimentation. In preferred embodiments, the content of diorgano tin compound having formula (2) is less than about 4 mol %, less than about 3 mol %, less than about 2 mol %, less than about 1 mol %, less than about 0.5 mol %, less than about 0.1 mol %, or even lower, as described above; the desired compound may also be obtained in high yield.

All of the method steps are preferably performed substantially without light exposure. Shielding may be accomplished by any method known in the art such as, for example and without limitation, employing light-shielded containers such as amber glass, metal (SUS) containers, wrapping the container with a light-shielding cover such as cloth, foil or film, using light-shielding coatings, or performing the reactions in a dark room.

The distillation may be performed using a stainless steel column packed with a stainless steel packing material. Alternatively, the distillation may be performed in a light-shielded apparatus comprising glass such as glass equipment, glass-lined equipment, glass-coated equipment, etc. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the distillation in a dark room.

In preferred embodiments, the methods described herein are performed in a solvent containing greater than about 50% by volume of an aliphatic hydrocarbon solvent and/or an aromatic hydrocarbon solvent such as, without limitation, those exemplified above. In preferred embodiments, the methods described herein are performed substantially without light exposure. In preferred embodiments, the solvents and reactants are dehydrated prior to use.

### Reduction of Additional Impurities

It is reasonable to presume that metallic impurities in organotin compounds are present as metal chlorides. If so, removal may be affected over an adsorbent, such as BASF CL-750, a chloride adsorbent known in the industry. Additional chloride impurities may be present, such as lithium chlorides which may be carried forward in the production process and become impurities of concern. Removal over a chloride-scavenging adsorbent, e.g., CL-750 or activated carbon may be effective for removal.

### Storage

Further aspects of the disclosure relate to methods of storing monoorgano tin compounds having formula (1) as described herein. A method of storing a sample (such as, but not limited to a sample of more than about 0.5 kg) of a monoorgano tin compound having formula (1) as described herein comprises storing the sample of the monoorgano tin compound having formula (1) substantially without light exposure and at any temperature, such as a temperature of less than about 30° C. The method may involve storing the compound having formula (1) in a container in an inert atmosphere and/or storing the compound having formula (1) in a container without light exposure such as, for example, in a dark room, by employing a light-shielded container such as amber glass, metal (SUS), wrapping the container with a light-shielding cover such as cloth, foil or film, using light-shielding coatings, etc.

The sample of the monoorgano tin compound having formula (1) may be stored for up to about three days to about one year, such as about a week or longer, not more than about ten months, a period of about two to six weeks, and all intermediate times as desired. Preferably the sample is stored at a temperature of less than about 30° C., less than about 25° C., less than about 20° C., and preferably greater than about −10° C. “Substantively without light exposure” may be understood to mean that the sample is protected from light exposure to the greatest possible extent, such as by storage in an amber or stainless steel vessel or other means of light shielding as are known in the art and/or as described above. In embodiments, the sample of the monoorgano tin compound undergoes substantively no decomposition after a storage time of hours, up to about three days to about one year, or longer, as described above. Since monoorgano tin compounds may react with oxygen and water vapor, a container with gas barrier properties is preferably used for storage. The term “gas barrier properties” is well understood in the art. While glass and stainless steel have gas barrier properties, if a resin container is used for storage, it is preferable to use a gas barrier resins. To prevent exposure to oxygen and water vapor, the container is preferably sealed with an inert gas such as argon or nitrogen.

### Additional Aspects of the Disclosure

Further aspects of the disclosure relate to a monoorgano tin compound having formula (6) having a purity of at least about 95 mol % and containing less than about 5 mol % of a diorgano tin compound having formula (7):

R″Sn(NR₂)₃ (6)

R″₂Sn(NR₂)₂ (7)

wherein R″ is a linear or branched unsaturated hydrocarbon group having about 2 to about 20 carbon atoms and R is a linear or branched alkyl group having about 1 to about 10 carbon atoms. In preferred embodiments, R″ is an allyl group and R is a methyl group.

In view of the properties of the tin compounds having formula (1), they are useful as high purity and stable intermediates for other tin compounds, particularly those that are difficult to synthesize by known procedures, such as tin compound (6) which contains an unstable R″ group, in particular linear or branched alkenyl groups, and a NR₂ group.

A method for synthesizing a monoorgano tin compound having formula (6) in high purity tin from a high purity tin compound having formula (1) as an intermediate is also an embodiment of this disclosure.

This method comprises reacting a R″Sn(OR_{f})₃ compound with a compound containing a NR₂ group, wherein R″ is a linear or branched unsaturated hydrocarbon group having about 2 to about 20 carbon atoms, R_{f} is a fluorinated organic substituent having about 1 to about 20 carbon atoms, and R is a linear or branched alkyl group having about 1 to about 10 carbon atoms.

An exemplary reaction scheme for this method is:

R′Sn(OR_{f})₃+3Li(NR₂)→R′Sn(NR₂)₃

R′Sn(OR_{f})₃+3Mg(NR₂)₂→R′Sn(NR₂)₃

R′Sn(OR_{f})₃+3SiMe₃(NR₂)→R′Sn(NR₂)₃

Exemplary compounds containing a NR₂ group include HNR₂, LiNR₂, NaNR₂, KNR₂, Mg(NR₂)₂, Zn(NR₂)₂, Al(NR₂)₃, SiMe₃(NR₂). Among these compounds, reagents containing Li, Na, and K, Si are preferred in terms of reactivity. Particularly, when the R′ in the tin compound having formula (1) is R″ (an unsaturated organic group), SiMe₃(NR₂) which has functional group selective reactivity is most preferred because of the coexistence with R″ groups.

Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction. Additionally, ethers, such as the most preferred THF, are presently preferred solvents because of the high solubility of compounds containing a NR₂ group in these types of solvents. It is also preferable to use mixtures of these solvents, such as mixtures of hydrocarbons and/or aromatics with ethers to obtain a high purity product through reaction and purification.

Lower preferred temperatures for the reaction are about −78° C., about −40° C., about −20° C., about −10° C., most preferably about 0° C., as well as all intervening temperatures, and the upper limit of the reaction temperature is preferably about 150° C., about 120° C., about 100° C., the most preferred upper limit of about 80° C. as well as all intervening temperatures. If the temperature is too low, the reaction rate will be too slow, whereas if the temperature is too high, byproducts will be produced. When byproducts are particularly problematic in the reaction, the process is preferably performed under reduced pressure to remove byproduct compounds.

A solution containing the compound containing a NR₂ group preferably has a concentration of up to about 3 M (mol/L), more preferably up to about 2 M, most preferably up to about 1 M, or a weight concentration (wt %) of up to about 30 wt %, more preferably up to about 20 wt %, most preferably up to about 15 wt %. The concentration is preferably greater than about 0.001 M, greater than about 0.01 M, greater than about 0.05 M, even more preferably greater than about 0.1 M, or greater than about 1 wt %, greater than about 2 wt %, greater than about 3 wt %, even more preferably greater than about 5 wt %.

It has been found that such dilute concentrations provide effective control of reaction temperature or solubility of compounds containing an NR₂ group. On the other hand, the productivity is lower in dilute concentrations in industrial conditions.

The concentration of the R′Sn(OR_{f})₃ compound in solution is preferably up to about up to about 30 wt %, more preferably up to about 20 wt %, most preferably up to about 15 wt %. The concentration is preferably greater than about 1 wt %, greater than about 2 wt %, greater than about 3 wt %, even more preferably greater than about 5 wt %. However, the appropriate solvent and concentrations of the reactants may be determined by routine experimentation.

The molar amount of the compounds containing a NR₂ group relative to R′Sn(OR_{f})₃ is preferably greater than about 3.0 equivalents, greater than about 3.05 equivalents, greater than about 3.09 equivalents, greater than about 3.10 equivalents, or greater than about 3.15 equivalents. If the relative amount of the OR_{f} compound is too low, the reaction speed may be too low and the amount of impurities may increase due to side reactions such as redistribution.

Following reaction of the two components, the reaction mixture is worked up and purified using methods well known in the art to produce the compound having formula R″ Sn(NR₂)₃. Especially, it is effective for producing tin compound R″Sn(NR₂)₃ in high purity, if the reaction condition is mild and there is good coexistence with R″ groups; the resulting reaction mixture contains low amounts of byproduct and it is easy to obtain the R″Sn(NR₂)₃ in high purity.

### Films

The organometallic tin compounds having formulas (1) and (6) form oxostannate cluster films on a silicon wafer after vapor phase deposition or spin-on coating processes. It has been found that a structure containing a small hydrocarbon ring bonded directly to a Sn atom provides more radiation sensitive Sn—C bonds that can be used to pattern structures lithographically. These are advantageous for EUV photoresists because the orbital interaction of the small cyclic hydrocarbon affects the Sn—C bond strength or the electronic state of tin, resulting in higher photosensitivity. When the organic group attached to the Sn atom stabilizes the radical generated by the cleavage of the Sn—C bond, as in the case of secondary alkyl, tertiary alkyl, allyl, and benzyl groups, the cleavage energy of the Sn—C bond is reduced, resulting in higher photosensitivity.

The radicals and anions generated by EUV light may react with small cyclic hydrocarbon rings and ring-opening polymerize to form stronger R′SnO_{(3/2-x/2)}(OH)ₓ (0<x≤3) films. The above reactions cause the R′SnO_{(3/2-x/2)}(OH)ₓ (0<x≤3) cluster film in the irradiated area to change greatly, resulting in a higher contrast as a resist.

Further aspects of the disclosure relate to organotin compounds having formula (8):

R′SnO_{(3/2-x/2)}(OH)ₓ (8)

In formula (8), 0<x≤3 and R′ is as defined above. Such compounds having formula (8) may be obtained by hydrolysis of a monoorgano tin compound having formula (1) as described herein.

Additional aspects of the disclosure relate to solutions containing organotin compounds having formula (8) and an organic solvent such as, without limitation, a hydrocarbon solvent or an aromatic solvent as described above. Further aspects of the disclosure relate to films containing organotin compounds having formula (8) as described herein, which may be obtained by hydrolysis as previously explained.

Additional aspects of the disclosure relate to a composition containing an organotin compound having formula (8) and an organotin compound having formula (9):

R′SnO_{(3/2-x/2)}(OH)ₓ (8)

R″SnO_{(3/2-y/2)}(OH)_{y} (9)

In formulas (8) and (9), 0<x≤3, 0<y≤3, R′ and R″ have been described previously. Such compounds having formula (8) and (9) may be obtained by hydrolysis of a monoorgano tin compound having formula (1) and (6) as described herein. If the compounds having formula (8) and (9) are obtained from mixtures of formula (1) and formula (6) compounds, the compounds having formula (8) and (9) may exist in the same molecule. A compound which has formula (8) and (9) compounds in the same molecule is preferable in terms of high uniformity of solubility and molecular weight for use as resist materials.

Further aspects of the disclosure relate to a solution containing an organic solvent as described herein and a composition containing organotin compounds having formula (8) and formula (9), which may, in some embodiments, be obtained by hydrolysis of a monoorgano tin compound having formula (1) and (6) as described herein. Additional aspects of the disclosure relate to films prepared from or containing a composition containing organotin compounds having formula (8) and (9).

The compounds described herein may be used as resist materials after hydrolysis or other reactions such as those known in the art. The compounds described herein may contain a group which is capable of forming an alkyltin oxo-hydroxo-patterning composition which may be hydrolyzed with water or other suitable reagents under suitable conditions to form an alkyltin oxo-hydroxo-patterning composition which may be represented by the formula R′SnO_{(3/2-x/2)}(OH)ₓ (0<x≤3). Hydrolysis and condensation reactions that may alter a compound with hydrolytic groups (X) are shown in the following reactions:

RSnX₃+3H₂O→RSn(OH)₃+3HX

RSn(OH)₃—RSnO_{(1.5-(x/2}))OHx+(x/2)H₂O

Alkyl oxohydroxy tin compounds obtained by hydrolysis using a composition containing R′SnX₃ compounds as described above as raw material and the oxohydroxy tin compounds represented by the formula R′SnO_{(3/2-x/2)}(OH)ₓ (0<x≤3) may be used as an EUV resist material.

A method for obtaining oxohydroxy tin compounds (R′SnO_{(3/2-x/2)}(OH)ₓ (0<x≤3)) by hydrolyzing a composition containing a R′SnX₃ compound may involve, for example, volatilizing a composition containing a R′SnX₃ compound under heating or reduced pressure, and reacting the vapor generated by volatilizing the composition on a substrate on which the tin composition is deposited, with water vapor, etc. (a dry method). In this method, a thin film containing the tin compound R′SnO may be formed on the substrate.

Another method may involve reacting a composition containing a R′SnX₃ compound in solution or in a solid state with water, etc., and hydrolyzing it to obtain the oxohydroxy tin compounds (R′SnO). The oxohydroxy tin compounds (R′SnO) may then be used as a coating solution by dissolving it in an organic solvent, for example. The organic solvent is not limited, however, in particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-propanol, 1-butanol, methanol, isopropyl alcohol, 1-propanol), ketones (e.g., methyl ethyl ketone), halogen solvents (e.g., CH₂Cl₂, CHCl₃) and mixtures thereof. In general, organic solvent selection may be influenced by solubility parameters, volatility, flammability, toxicity, viscosity and potential chemical interactions with other processing materials.

The solution may be applied to a substrate by any coating or printing technique, and a thin film or coating containing oxohydroxy tin compounds (R′SnO) may be formed on the substrate. After the components of the solution are dissolved and combined, the character of the species may change as a result of partial hydration and condensation, especially during the coating process.

The thin film obtained by any of the above methods may be stabilized or partially condensed prior to light irradiation through drying, heating, or other processes. Generally, thin films or coatings have an average thickness of less than about 10 microns, and very thin submicron thin films, e.g., less than about 100 nanometers (nm), even less than about 50 nm or less than about 30 nm, may be desirable for patterning very small features. The resulting thin film or coating may be called a resist because the exposure processes a portion of the composition to be resistant to development/etching.

The thin film or coating may be exposed to appropriate radiation, (e.g., extreme ultraviolet, electron beam, deep ultraviolet, or ultraviolet), using a selected pattern or negative portion of the pattern to form a latent image with developer resistant and developer soluble regions. After exposure to the appropriate radiation and prior to development, the thin film or coating may be heated or otherwise reacted to further differentiate the latent image from the non-irradiated areas. The latent image is brought into contact with the developer to form a physical image, i.e., a patterned thin film or coating. The patterned thin film or coating may be further heated to stabilize the remaining patterned coating on the surface. The patterned coating may be used as a physical mask to perform further processing according to the pattern, e.g., etching of the substrate and/or attachment of additional materials. After the patterned resist is used as requested, the remaining patterned coating may be removed at an appropriate point in the processing, but the patterned coating may also be incorporated into the final structure.

The invention will now be described in connection with the following, non-limiting examples.

### Example 1-1: Synthesis of Isopropyl tris(2,2,2-trifluoroethoxy)tin

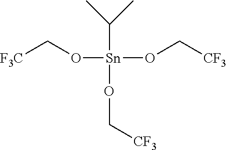 [SMILES: C[CH](C)[Sn]([O]CC(F)(F)F)([O]CC(F)(F)F)[O]CC(F)(F)F]

iPrSn(NMe₂)₃ was prepared according to the method described in U.S. Patent Application Publication No. 2023/0391804. In a 100 mL flask were placed iPrSn(NMe₂)₃ (4.1 g, 13.9 mmol) and n-hexane (5 mL) under N₂ and cooled to 0° C. 2,2,2-Trifluoroethanol (4.5 g, 44.5 mmol) was added dropwise while maintaining the pot temperature at 0° C. to 10° C. The mixture was warmed to 50° C. and stirred for an additional 2 hours. The solvent was removed under reduced pressure to yield the title compound. The product was filled into amber vessels without light exposure and stored under an inert gas atmosphere. ¹¹⁹Sn NMR (400 mHz; CDCl₃): δ−395(br), −509 (assumed to be a tin oligomer form as reported in Organotin Chemistry, Second Edition Second, Completely Revised and Updated Edition, page 218) (2004). ¹H NMR (400 mHz; CDCl₃): δ 4.4-4.0 (m. 6H), 2.2-2.0 (m, 1H), 1.49 (m, 6H). Purity: >99%.

### Example 1-2: Synthesis of Isopropyl tris(1,1,1,3,3,3-hexafluoro-2-propoxy)tin

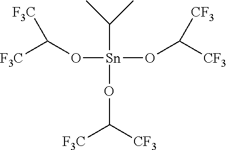 [SMILES: C[CH](C)[Sn]([O]C(C(F)(F)F)C(F)(F)F)([O]C(C(F)(F)F)C(F)(F)F)[O]C(C(F)(F)F)C(F)(F)F]

iPrSn(NMe₂)₃ was prepared according to the method described in U.S. Patent Application Publication No. 2023/0391804. In a 100 mL flask were placed iPrSn(NMe₂)₃ (4.1 g, 13.9 mmol) and n-hexane (5 mL) under N₂ and cooled to 0° C. 1,1,1,3,3,3-Hexafluoropropan-2-ol (HFIP, 7.48 g, 44.5 mmol) was added dropwise while maintaining the pot temperature at 0 to 10° C. The mixture was warmed to 50° C. and stirred for an additional 2 hours. The solvent was removed under reduced pressure to yield the title compound. The product was filled into amber vessels without light exposure and stored under an inert gas atmosphere. ¹¹⁹Sn NMR (400 mHz; CDCl₃): δ−429, −467 (assumed to be a tin oligomer form as reported in Organotin Chemistry, Second Edition Second, Completely Revised and Updated Edition, page 218) (2004); ¹H NMR (400 mHz; CDCl₃): δ 5.0-4.5 (m. 3H), 2.2-2.0 (m, 1H), 1.40 (m, 6H). Purity: >99%.

### Example 1-3 Synthesis of Allyltris((1,1,1-trifluoro-2-methylpropan-2-yl)oxy)tin

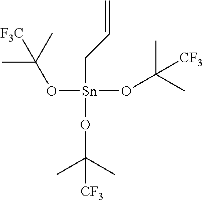 [SMILES: C=C[CH2][Sn]([O]C(C)(C)C(F)(F)F)([O]C(C)(C)C(F)(F)F)[O]C(C)(C)C(F)(F)F]

Allyltin trichloride was prepared according to the method of Rosenberg and Gibbons (JACS, 79, 2138-40 (1957)) by the redistribution reaction of tetraallyltin and tetrachlorotin. A 2.5 M solution of n-butyl lithium in hexanes (230 g, 0.83 mol) was charged into a 2 L flask and cooled to −30° C. To this solution 1,1,1-trifluoro-2-methyl-2-propanol (100 g, 0.78 mol) was added dropwise over the course of 30 min resulting in a vigorous exothermic reaction. The reaction temperature was maintained below 5° C. over the course of the addition, during which time an orange solution and some white solids formed. The reaction was warmed to room temperature, the walls of the reactor were rinsed with hexanes (300 g), and the reaction was stirred for an additional 2 h. After stirring at room temperature, the reaction mixture was cooled to −10° C. and a solution of allyltrichlorotin (69 g, 0.26 mol) in toluene (150 g) was added to the reaction mixture in portions over the course of 10 min, during which time the orange solution became a light-yellow color and a white precipitate formed. The reaction mixture was warmed to room temperature and stirred for 16 h. The resulting light-yellow solution was isolated by filtration and the solvent was removed from the filtrate under vacuum with gentle heating (5 torr, 35° C.) giving a viscous yellow liquid. The product was isolated as a colorless liquid after distillation without light exposure. The product was filled into amber vessels without light exposure and stored under an inert gas atmosphere. Yield=40 g (30%): bp 65° C. at 0.5 torr. ¹H NMR (benzene-d₆): δ 1.30 (s, 18H, OC(CH₃)₂CF₃), δ 2.15 (d, 2H, SnCH₂CHCH₂), δ 4.86 (m, 2H, SnCH₂CHCH₂), δ 5.57 (m, 1H, SnCH₂CHCH₂). ¹¹⁹Sn{¹H}NMR: δ −253. Purity: >97%.

### Example 2-1: (Prophetic): Synthesis of isopropyl tris(dimethylamino)stannane from isopropyl tris(2,2,2-trifluoroethoxy)tin

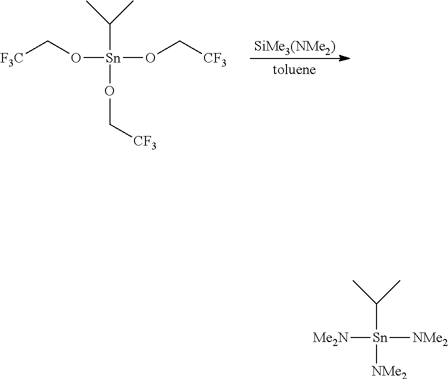 [SMILES: C[CH](C)[Sn]([O]CC(F)(F)F)([O]CC(F)(F)F)[O]CC(F)(F)F ; "SiMe3(NMe2)" ; C[CH](C)[Sn]([N](C)C)([N](C)C)[N](C)C]

In a 100 mL flask are placed isopropyl tris(2,2,2-trifluoroethoxy)tin (4.6 g, 10.0 mmol, prepared in Example 1-1) and toluene (20 mL) under N₂ at room temperature. SiMe₃(NMe₂) (3.87 g 33.0 mmol, 3.3 eq) is added to the mixture at room temperature and the mixture is warmed at 70° C. and stirred for 12 h. After the reaction, the compound is obtained from the mixture by distillation at reduced pressure without light exposure. The product is filled into amber vessels without light exposure and stored under an inert gas atmosphere. The purity of the title compound is >99%.

### Example 2-2 (Prophetic): Synthesis of isopropyl tris(dimethylamino)stannane from isopropyl tris(1,1,1,3,3,3-hexafluoro-2-propoxy)tin

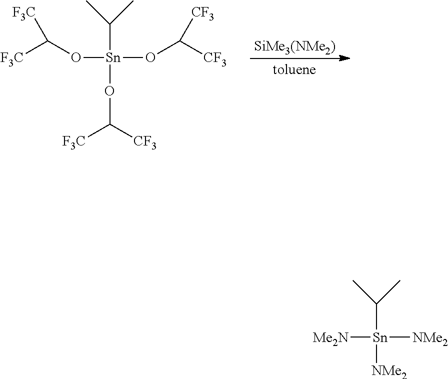

In a 100 mL flask are placed isopropyl tris(1,1,1,3,3,3-hexafluoro-2-propoxy)tin (6.6 g, 10.0 mmol, prepared in Example 1-2) and toluene (20 mL) under N₂ at room temperature. SiMe₃(NMe₂) (3.87 g 33.0 mmol, 3.3 eq) is added to the mixture at room temperature and the mixture is warmed at 70° C. and stirred for 12 h. After the reaction, the compound is obtained from the mixture by distillation at reduced pressure without light exposure. The product is filled into amber vessels without light exposure and stored under an inert gas atmosphere. The purity of the title compound is >99%.

### Example 2-3 (Prophetic): Synthesis of allyltris(dimethylamino)tin from allyltris((1,1,1-trifluoro-2-methylpropan-2-yl)oxy)tin

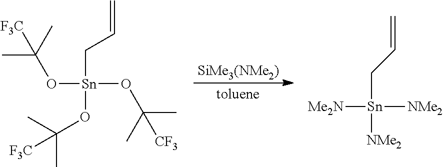

In a 100 mL flask are placed allyltris((1,1,1-trifluoro-2-methylpropan-2-yl)oxy)tin (5.4 g, 10.0 mmol) of Ex 1-3 and toluene (20 mL) under N₂ at room temperature. SiMe₃(NMe₂) (3.87 g 33.0 mmol, 3.3 eq) is added to the mixture at room temperature and the mixture is warmed at 70° C. and stirred for 12 h. After the reaction the title compound is obtained from the mixture by distillation at reduced pressure. The product is filled into amber vessels without light exposure and stored under an inert gas atmosphere. The purity of the title compound is >99%.

### Example 3-1 (Prophetic): Preparation and Analysis of R′SnO_{(3/2-x/2)}(OH)ₓ Compounds (where 0<x≤3) by Hydrolysis

To a 100-mL flask under an inert gas atmosphere are added 10 mL n-hexane (dehydrated) and 1.0 g isopropyl tris(2,2,2-trifluoroethoxy)tin, which is synthesized as described in Example 1-1, and dissolved with stirring at 150 rpm. After cooling the resulting solution to 0-10° C., demineralized water (1.0 mL, resistance 18.2 MΩ) is added by syringe over 10 minutes while stirring at 150 rpm and maintaining a temperature of 0-10° C. to form a suspension. The resulting suspension is filtered through a funnel (Kiriyama filter paper 5B) to obtain a white solid. The resulting white solid is washed with 3 mL of demineralized water and then dried in vacuo at 40° C. for 8 h. The resulting white solid (SnO-1) product is filled into amber vessels without light exposure and stored under an inert gas atmosphere.

SnO-1 is identified by NMR using a Bruker Avance Neo 600 MHz Probe: cryo 5 mm BBO and by ESI-Mass spectroscopy to be a compound corresponding to R′SnO_{(3/2-x2)}(OH)ₓ (where 0<x≤3).

### Example 3-2 (Prophetic): Preparation and Analysis of Mixture of R′SnO_{(3/2-x2)}(OH)ₓ and R″SnO_{(3/2-y/2)}(OH)_{y} (where 0<x≤3, 0<y≤3) by Hydrolysis

A white solid (SnO-2) is obtained from 0.7 g of the compound prepared as described in Example 1-1 and 0.3 g allyltris(dimethylamino)tin as described in Example 2-3 using the same method described in Example 3-1. The product is filled into amber vessels without light exposure and stored under an inert gas atmosphere.

SnO-2 is identified by NMR using a Bruker Avance Neo 600 MHz Probe: cryo 5 mm BBO) and ESI-Mass spectroscopy to be a compound corresponding to R′SnO_{(3/2-x/2)}(OH)ₓ and R″SnO_{(3/2-y/2)}(OH)_{y} (where 0<x≤3, 0<y≤3) which are blended in the same molecule.

### Example 4-1 (Prophetic): Preparation of Film

The SnO-1 of Example 3-1 is dissolved in chloroform (5 mL) to a concentration of 2.0 wt % while using ultrasonic waves, and the resulting solution is filtered through a 0.20 μm syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin coated onto the substrate at 2000 rpm and baked on a hot plate at 90° C. for 2 minutes. The film thickness after coating and baking is measured by ellipsometer.

### Example 4-2 (Prophetic): Preparation of Film

The SnO-2 of Example 3-2 is dissolved in chloroform (5 mL) to a concentration of 2.0 wt % while using ultrasonic waves, and the resulting solution is filtered through a 0.20 um syringe filter to obtain a resist solution containing a transparent tin compound. Silicon wafers with oxide surfaces (Si substrate, 100 mm diameter) are ozonated and used as 25 substrates for resist thin film deposition. The surface of the Si substrate is treated with hexamethyldisilazane (HMDS) vapor prior to resist deposition. The resist solution is spin-coated onto the substrate at 2000 rpm and baked on a hot plate at 90° C. for 2 minutes. The film thickness after coating and baking is measured by ellipsometer.

### Example 5-1 (Prophetic): Formation of Image on Substrate

The coated substrate (film) from Example 4-1 is exposed to ultraviolet light (light source: xenon excimer lamp (172 nm, 7.2 eV) manufactured by USHIO INC., light source intensity: 0.7 mW/cm2) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

### Example 5-2 (Prophetic): Formation of Image on Substrate

The coated substrate (film) from Example 4-2 is exposed to ultraviolet light (light source: xenon excimer lamp (172 nm, 7.2 eV) manufactured by USHIO INC., light source intensity: 0.7 mW/cm2) using a pattern to project a pattern on the substrate. The substrate is then immersed in 2-5 heptanone for 15 seconds and rinsed with the same developer for another 15 seconds to form a negative-type image, i.e., an image in which the unexposed portion of the thin film is removed and only the pattern-exposed portion remains.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A monoorgano tin compound having formula (1) having a purity of at least about 95 mol % and containing less than about 5 mol % of a diorgano tin compound having formula (2):
R′SnX₃ (1)
R′₂SnX₂ (2)
wherein R′ is an optionally substituted organic substituent having about 1 to about 20 carbon atoms and each X is independently OR_{f}, wherein R_{f} is a fluorinated organic substituent having about 1 to about 20 carbon atoms.

2. The monoorgano tin compound according to claim 1, wherein R′ is substituted with at least one halogen, oxygen, and/or nitrogen atom.

3. The monoorgano tin compound according to claim 1, wherein a total content of a tin compound having formula (3) is less than about 5 mol %:
R′₃SnX (3).

4. The monoorgano tin compound according to claim 1, wherein a total content of a tin compound having formula (4) is less than about 5 mol %
R′₄Sn (4).

5. The monoorgano tin compound according to claim 1, wherein a total content of a tin compound having formula (5) is less than about 5 mol %:
SnX₄ (5).

6. The monoorgano tin compound according to claim 1, wherein R_{f} is a linear or branched alkyl, aryl, or aralkyl group.

7. The monoorgano tin compound according to claim 1, wherein R_{f} is a linear or branched fluorinated alkyl group.

8. The monoorgano tin compound according to claim 1, wherein R_{f} is selected from: 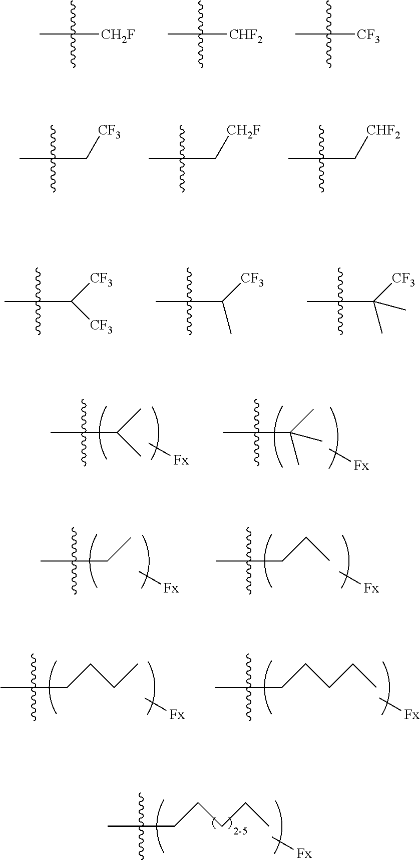
wherein Fx indicates that at least one hydrogen atom in brackets is replaced by one or more fluorine atoms.

9. The monoorgano tin compound according to claim 1, wherein R_{f} contains at least three fluorine atoms.

10. A method of synthesizing a monoorgano tin compound having formula (1):
R′SnX₃ (1)
wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting a compound containing an R′ group with a compound having formula (5):
SnX₄ (5).

11. The method according to claim 10, wherein the compound containing an R′ group is a compound having formula R′MgZ, wherein Z is a halogen atom.

12. A method of synthesizing a monoorgano tin compound having formula (1):
R′SnX₃ (1)
wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising reacting an R′SnY₃ compound with a compound containing an OR_{f} group, wherein Y is a halogen atom, an alkoxy group, or a dialkylamino group.

13. The method according to claim 12, wherein Y is a dialkylamino group.

14. The method according to claim 12, wherein R′SnY₃ is prepared by reacting a R′₄Sn compound with a SnY₄ compound.

15. A method of synthesizing a monoorgano tin compound having formula (1):
R′SnX₃ (1)
wherein R′ is an optionally substituted organic substituent having about 1 to about 20 carbon atoms and each X is independently OR_{f}, wherein R_{f} is a fluorinated organic substituent having about 1 to about 20 carbon atoms, the method comprising:
(a) reacting a metal compound comprising an alkali metal M and a ligand X with a compound having formula SnY₂ to form a compound having formula MSnX₃; and
(b) reacting the compound having formula MSnX₃ with a compound R′Z, wherein Z is a halogen atom and Y is a halogen atom, an alkoxy group, or a dialkylamino group.

16. The method according to claim 10, wherein the reaction is performed in a solvent containing greater than about 50% by volume of an aliphatic hydrocarbon solvent and/or an aromatic hydrocarbon solvent.

17. The method according to claim 16, wherein the solvent is dehydrated prior to performing the reaction.

18. The method according to claim 10, further comprising at least one purification step substantially without light exposure.

19. The method according to claim 18, wherein the at least one purification step comprises fractional distillation.

20. The method according to claim 10, wherein the reaction is performed substantially without light exposure.

21. A method of storing a sample of the monoorgano tin compound having formula (1) according to claim 1, the method comprising storing the sample of the monoorgano tin compound having formula (1) substantively without light exposure and at a temperature of less than about 30° C.

22. The method according to claim 21, wherein the sample of the monoorgano tin compound having formula (1) is stored for about three days to about one year.

23. The method according to claim 21, wherein the sample of the monoorgano tin compound undergoes substantively no decomposition after a storage time of about three days to about one year.

24. The method according to claim 21, comprising storing the compound having formula (1) in a container in an inert atmosphere.

25. The method according to claim 21, comprising storing the compound having formula (1) in a container substantially with gas barrier properties.

26. A monoorgano tin compound having formula (6) having a purity of at least about 95 mol % and containing less than about 5 mol % of a diorgano tin compound having formula (7):
R″Sn(NR₂)₃ (6)
R″₂Sn(NR₂)₂ (7)
wherein R″ is a linear or branched unsaturated hydrocarbon group having about 2 to about 20 carbon atoms and R is a linear or branched alkyl group having about 1 to about 10 carbon atoms.

27. The monoorgano tin compound having formula (6) according to claim 26, wherein R″ is an allyl group and R is a methyl group.

28. A method of synthesizing a monoorgano tin compound having formula (6):
R″Sn(NR₂)₃ (6)
the method comprising reacting a R″Sn(OR_{f})₃ compound with a compound containing a NR₂ group, wherein R″ is a linear or branched unsaturated hydrocarbon group having about 2 to about 20 carbon atoms, R_{f} is a fluorinated organic substituent having about 1 to about 20 carbon atoms, and R is a linear or branched alkyl group having about 1 to about 10 carbon atoms.

29. An organotin compound having formula (8):
R′SnO_{(3/2-x/2)}(OH)ₓ (8)
wherein the compound having formula (8) is obtained by hydrolysis of a compound having formula (1):
R′SnX₃ (1)
wherein 0<x≤3, R′ is an optionally substituted organic substituent having about 2 to about 20 carbon atoms and each X is independently OR_{f}, wherein R_{f} is a fluorinated organic substituent having about 1 to about 20 carbon atoms.

30. An organotin compound having formula (9), wherein the compound having formula (9) is obtained by hydrolysis of a compound having formula (6):
R″Sn(NR₂)₃ (6)
R″SnO_{(3/2-y/2)}(OH)_{y} (9)
wherein 0<y≤3, R″ is a linear or branched unsaturated hydrocarbon group having about 2 to about 20 carbon atoms and R is a linear or branched alkyl group having about 1 to about 10 carbon atoms.

31. A solution comprising the organotin compound having formula (8) and/or (9) according to claim 29 and an organic solvent.

32. A film comprising the organotin compound having formula (8) and/or (9) according to claim 29.

33. The monoorgano tin compound according to claim 1, wherein R′ is a linear or branched alkyl group.

34. A method of synthesizing a tin compound having formula (8):
R′SnO_{(3/2-x/2)}(OH)ₓ (8)
the method comprising hydrolyzing a compound having formula (1):
R′SnX₃ (1)
wherein 0<x≤3, R′ is an optionally substituted organic substituent having about 2 to about 20 carbon atoms and each X is independently OR_{f}, wherein R_{f} is a fluorinated organic substituent having about 1 to about 20 carbon atoms.

35. A method of synthesizing a tin compound having formula (9):
R″SnO_{(3/2-y/2)}(OH)_{y} (9)
the method comprising hydrolyzing a compound having formula (6):
R″Sn(NR₂)₃ (6)
wherein 0<y≤3, R″ is a linear or branched unsaturated hydrocarbon group having about 2 to about 20 carbon atoms and R is a linear or branched alkyl group having about 1 to about 10 carbon atoms.
